(19) United States
(12) Patent Application Publication
(10) Pub. No.: US 2010/0244871 A1
(43) Pub. Date: Sep. 30, 2010

(54) SPACE TRANSFORMER CONNECTOR PRINTED CIRCUIT BOARD ASSEMBLY

(75) Inventors: James L. Blair, San Diego, CA (US); David W. Waite, Oceanside, CA (US); Ashish Lohiya, La Jolla, CA (US); Saritha Narra, San Diego, CA (US); Jeffrey T. Smith, Poway, CA (US); Arvid G. Sammuli, Escondido, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/709,619

(22) Filed: Feb. 22, 2010

Related U.S. Application Data
(60) Provisional application No. 61/155,082, filed on Feb. 24, 2009.

(51) Int. Cl. G01R 31/02; H01R 12/14

(52) U.S. Cl. 324/755; 439/65; 324/754

(57) ABSTRACT

Space transformer connectors for coupling printed circuit boards and/or other electrical connections are disclosed. A scalar design of a multilayer space transformer connector allows for a variety of pad-array field connections. A conductive elastomer interface provides for repeated and consistent coupling and decoupling of the space transformer connector.

### CLAIM OF PRIORITY UNDER 35 U.S.C. §119

The present application for patent claims priority to Provisional Application No. 61/155,082 entitled “3-D SPACE TRANSFORMER (3D-SPACEX) CONNECTOR PRINTED CIRCUIT BOARD ASSEMBLY” filed Feb. 24, 2009, and assigned to the assignee hereof and hereby expressly incorporated by reference herein.

### FIELD OF DISCLOSURE

The disclosed embodiments are related to space transformers for coupling printed circuit boards. In particular embodiments are directed to space transformer connector printed circuit board assemblies.

### BACKGROUND

Printed circuit boards (PCBs) are the means of choice to interconnect a wide variety of electronic circuits and associated components into electronic or electro-mechanical assemblies capable of performing a nearly unlimited number of tasks ranging from ultra miniature surveillance devices to mainframe supercomputers. The PCB assemblies can range in size from sub-square millimeter to a square meter and beyond. An art form in PCB manufacturing is to reliably produce fine-pitched circuits of conductor material (typically copper; CU) on physically large circuit boards, for example, 0.5 mm component pin spacing on a 32-layer 18″×24″×0.18″ PCB. Manufacturing these type of PCBs are a feat presently attainable by only a select few PCB fabricators worldwide. This feat becomes highly problematic at a component pin spacing of 0.4 mm and smaller and nearly unattainable in designs requiring multiple fine pin-pitch ICs distributed over a large surface area. Greatly facilitating sub 0.5 mm circuit geometries and board fabrication yield is the allowance of smaller/thinner PCBs.

Unfortunately, a small circuit board will rarely hold a large amount of circuitry. To merge the best of both worlds, a motherboard (MB)/daughter card (DC) space transformer technology has developed within the electronic industry wherein a relatively smaller PCB assembly is mounted atop a larger PCB assembly and electrically interfaced by one or more connector means. With this three dimensional approach, board surface area immediately adjacent to and directly under the footprint of these high density fine pin-pitch ICs is effectively doubled with top and bottom board surface areas of both the DC and MB available for support component placement. Prior art MB/DC connections have utilized two-part (male/female) connectors typically of the commercially available type with some being of the custom variety.

FIG. 1 illustrates a conventional motherboard (MB) 110/daughter card (DC) 120 assembly showing two board-top mounted integrated circuit (IC) sockets 101 flanked by three board bottom-side plug/socket interface connectors (102/112, 104/114, 106/116). The combined assembly is made mechanically integral by the optional use of metal board-joining rails. These board interface connectors may be provisioned to pass signals with frequencies ranging from DC to multi-GHz. Typically and for a given connector size, the signal pin count decreases with increasing frequency handling capability as additional ground pins become necessary to assure high signal integrity. This reduced pin count becomes problematic with multiple hundreds to greater than the one thousand pin-count of modern multi-GHz capable ICs.

### SUMMARY

Exemplary embodiments are related to space transformers for coupling printed circuit boards. Embodiments offer a monolithic high pin-density, high signal integrity (extremely wide band) PCB alternative to two-part connector prior art. The use of 3D-SpaceX PCB based printed electrical connectors can afford a higher pin count per unit area compared to alternative connectors.

Accordingly, an embodiment includes a space transformer connector formed of a multilayer printed circuit board comprising: a plurality of ground planes separated by layers of dielectric material in the PCB; a plurality of conductive vias extending at least partially through the PCB; a pad-array field having a plurality of contact pads located on opposing surfaces of the PCB, which are coupled to the conductive vias; and at least one coaxial mount for alignment and mounting, wherein the coaxial mount is located adjacent the pad-array field.

Another embodiment includes an assembly comprising a daughter card coupled to a device-under-test (DUT) configured to distribute signals from the DUT to a first contact array; a mother board having a second contact array; a space transformer connector formed of a multilayer printed circuit board (PCB) having a connector portion comprising: a plurality of ground planes separated by layers of dielectric material in the PCB; a first pad-array field having a plurality of contact pads located on a first surface of the PCB configured to couple to the first contact array; a second pad-array field having a plurality of contact pads located on a second surface of the PCB configured to couple to the second contact array; a plurality of conductive vias extending at least partially through the PCB to couple the first and second pad-array fields; and at least one coaxial mount for alignment and mounting, wherein the coaxial mount is located adjacent the first and second pad-array fields; a first conductive elastomer disposed over the first pad-array field, wherein the first conductive elastomer is configured to electrically couple the first pad-array field to the first contact array; and a second conductive elastomer disposed over the second pad-array field, wherein the second conductive elastomer is configured to electrically couple the second pad-array field to the second contact array.

Another embodiment includes a space transformer connector formed of a multilayer printed circuit board (PCB) comprising: means for providing ground connections separated by layers of dielectric a dielectric means in the PCB; means for providing electrical conductivity extending at least partially through the PCB; means for providing electrical contact having a plurality of contact pads located on opposing surfaces of the PCB, which are coupled to the means for providing electrical conductivity; and means for aligning and mounting in an integrated unit, wherein the means for aligning and mounting is located adjacent means for providing electrical contact.

### BRIEF DESCRIPTION OF THE DRAWINGS

The accompanying drawings are presented to aid in the description of the disclosed embodiments and are provided solely for illustration of the embodiments and not limitation thereof.

FIG. 1 is an illustration of a daughter card mounted atop a space transformer configuration including a conventional two-part connector arrangement.

FIG. 2A illustrates a conventional arrangement of connector pin-fields and alignment located on opposite ends of a daughter card.

FIGS. 2B & 2C illustrate different arrangements of three 3D-SpaceX connectors located on opposite ends of a spacer PCB.

FIG. 3 illustrates an arrangement of two 3D-SpaceX connectors located on opposite ends of a daughter card.

FIG. 4A is a detailed illustration of a 3D-SpaceX connector including details of a pad-array field, in one embodiment.

FIG. 4B is a detailed illustration of a portion of the pad-array field of FIG. 4A.

FIG. 5 illustrates several alternative configurations 3D-SpaceX connectors.

FIG. 6 illustrates two circular alternative of 3D-SpaceX connectors located on opposite ends a common spacer PCB.

FIG. 7 illustrates an arrangement of two 3D-SpaceX connectors pin-fields located on opposite ends of a daughter card footprint including wide bandwidth couplings to RF connectors located on a motherboard.

FIG. 8 illustrates an arrangement multiple superimposed 3D-SpaceX connector PCB footprints atop a compatible motherboard including couplings to RF connectors located on a motherboard.

FIG. 9A illustrates a plan view of two 3D-SpaceX connectors formed on a common PCB and located on opposite ends.

FIG. 9B illustrates an end view of two 3D-SpaceX connectors formed on a common PCB and located on opposite ends.

FIG. 10 illustrates an arrangement of multiple 3D-SpaceX connectors formed on a common PCB.

FIGS. 11A-C illustrate various aspects of the construction of a 3D-SpaceX connector including a conductive elastomer interface and example PCB via construction illustrating multiple signal ground planes.

FIG. 12 illustrates a side view of an arrangement multiple integral 3D-SpaceX connectors and daughter card formed on a common PCB.

FIG. 13 illustrates an assembly for an integrated circuit test system including individual (free-standing) 3D-SpaceX connectors.

FIGS. 14A and 14B illustrate an assembly for a circuit test system including 3D-SpaceX connectors, a coaxial mounting and a two-mount socket.

FIGS. 15A-15C illustrate a configuration of 3D-SpaceX connectors having edge connectors and an internal shelf.

FIGS. 16A-16C illustrate a configuration of 3D-SpaceX connectors having edge connectors, an internal shelf and a pedestal arrangement.

### DETAILED DESCRIPTION

Aspects are disclosed in the following description and related drawings directed to specific embodiments. Alternate embodiments may be devised without departing from the scope of the invention. Additionally, well-known elements of the disclosed embodiments will not be described in detail or will be omitted so as not to obscure the relevant details of the disclosed embodiments.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments include the discussed feature, advantage or mode of operation. Further, the dimensions illustrated and applications discussed herein are merely for illustration of embodiments and do not limit the embodiments to these specific examples.

The terminology used herein is for the purpose of describing particular embodiments only and is not intended to be limiting of embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof. As used herein the terms 3D-SpaceX, 3D-SpaceX connector and space transformer connector may be used interchangeably.

In the illustrated embodiments provided herein, some dimensional information is provided to give a reference to the scale and relative sizes of elements in various embodiments. However, these examples and illustrations are provided solely to facilitate discussion and understanding of embodiments and are not to be construed as limiting embodiments to the disclosed dimensions, scale, and/or relative sizes of elements.

As illustrated in the disclosed embodiments, a daughter DC and MB are mechanically arranged and the circuit is configured to sandwich a discrete-signal electrically conductive three-dimensional PCB based high density pad-array field space transformer connector (3D-SpaceX) between them. A 3D-SpaceX connector (or connector portion) is generally used herein as the combination of pad-array field, PCB mounting and alignment features, and any feature(s) used to accommodate a conductive medium between the pad-array field electrical interface between the connector portion and the DC and/or MB. As used herein the term pad can include a pin/contact on a surface of a PCB which may be coupled to conductive vias which provide for conduction of the electrical signal inside and through the PCB. The pad-array (or pin-array) is defined herein as an arrangement of electrical pad/pins/contacts within a pad-array field. DC/3D-SpaceX/MB interface continuity is established and sustained subject to a compression force typically provided by a spring-loaded alignment/restraint mechanism. The 3D-SpaceX Space Transformer includes one or more PCB based pad-array field connectors ranging in thickness from less than 2 mm to greater than 10 mm. Additionally, a space transformer connector as used herein may include one 3D-SpaceX connector portion and additional portions formed from a common PCB.

The 3D-SpaceX connector itself in embodiments includes a two-sided multi-layer circuit board configured with one or more opposing surface pad-arrays interconnected by conductive vias. Depending upon the 3D-SpaceX connector physical-electrical combination of pad, via, anti-pad, location/separation of parallel internal ground planes, number and location of signal grounds and, of course, the requisite insulator dielectric constant and loss tangent, individual connection electrical properties may be optimized to accommodate virtually any signal type ranging from high-current power and ground capable to those ultra-wideband signals found in multi-gigahertz frequency radio communications. Pad-array field pin/pad densities may be limited only by application specific requirements. For example, high current and/or voltage applications may require widely separated large pin pads and vias due in part to thermal considerations or dielectric high-pot strength resulting in only a few pads per square inch while low current signal connectivity may push pad count well beyond 2600 over the same surface area. The arrangement of 3D-SpaceX connector opposing conductive interconnected pads are replicated upon both the DC and MB electrical connection areas in some embodiments. In some embodiments, two or more space transformer connectors are free-standing (stand alone) connectors fabricated from the same or differing PCB material. Another exemplary embodiment includes fabricating the space transformer connector and all connector portions from a single monolithic PCB material and to machine the board space between connectors in a combination of entirely through board, to effectively mechanically isolate each connector portion, and can include optional device under test (DUT) integrated socket mounting pedestals and/or a DUT-center support pedestal. The DC/3D-SpaceX/MB interface can formed of a compressible electrically conductive medium which may include but is not limited to, spray-ons, conductive elastomers, or other suitable conductive elastomeric materials.

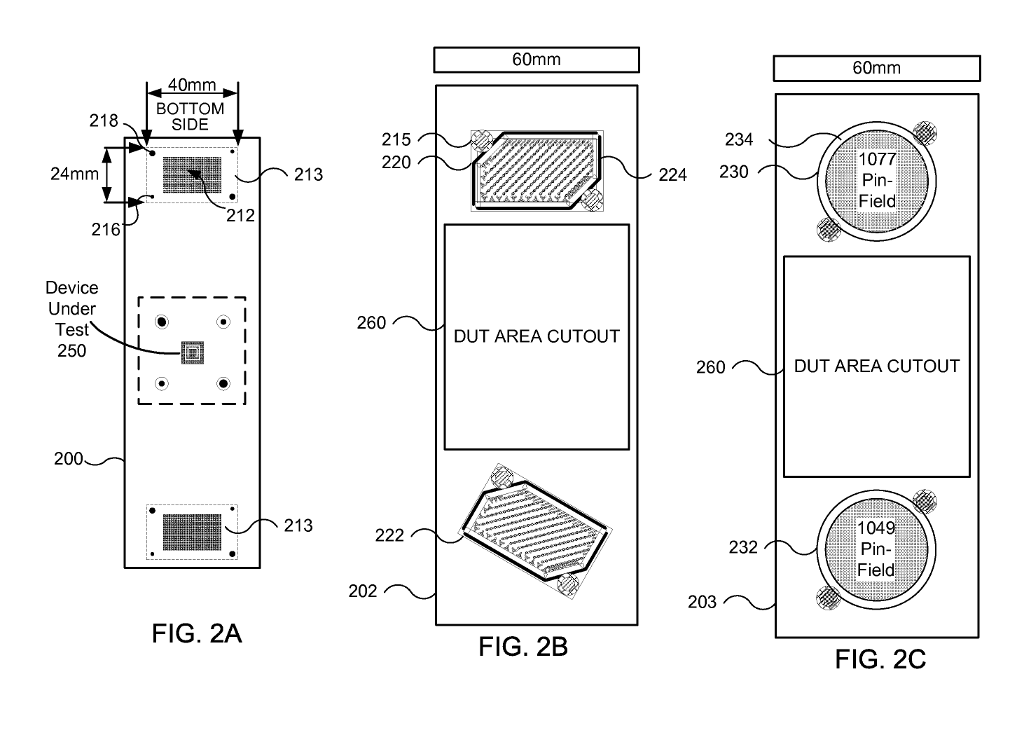

FIG. 2A illustrates a bottom view of a daughter card 200 that can include an area for mounting a socket for holding DUT 250 and one or more electrical connection areas 213 for mating connectors electrically couple DUT related signals to a motherboard. As used herein, DUT 250 will generally be interchangeably referred as either including the socket mount for the device under test or for direct device solder attachment for convenience of explanation. Additionally, it can be appreciated that embodiments may serve to support two or more DUT locations (not shown).

Each connector mating connection area 213 can include pins 212 that contains a plurality of connecting points for coupling daughter card signals to a motherboard or other electrical connection. Conventional mounting configurations include separate alignment points 216 and mounting points 218. As will be appreciated, two guide and mount points 216 can be used for registration (alignment) of a connector to the daughter card 200.

Referring to FIG. 2B, for example, embodiments of the spacer connector 202 include mounting and alignment functions may be included in one coaxial mounting element as discussed further herein. In contrast to the conventional configurations have utilized two discrete pin-field alignment means (e.g., 216) and four or more compressive mounting points (216, 218) per connector (see, e.g., FIG. 2A). As an alternative example, the daughter card/3D-SpaceX PCB/mother board mechanical coupling may be achieved by a gluing a pressure application mechanism to the MB

It will be further appreciated, referring to FIG. 2B, for example, that the 3D-SpaceX connectors are not necessarily symmetrical in physical arrangement (e.g., size, shape and/or orientation) and/or electrical arrangement (e.g., pad-array field arrangement), but are configured to align to corresponding contact pads of a daughter card and/or mother board. For example, as illustrated in FIG. 2B an embodiment of a spacer transformer connector (3D-SpaceX PCB) 202 can have first 3D-SpaceX connector 220 that is orientated substantially parallel to DUT cutout 260 and a second 3D-SpaceX connector 222 on an opposite side of DUT cutout 260 that is orientated at an angle relative to DUT cutout 260. In an exemplary embodiment milled or formed glue channels 224 are provided to mechanically attach a conductive elastomer (not shown) that is overlaid on each 3D-SpaceX connector pad-array surface (second surface not shown) to form the coupling points for the 3D-SpaceX connector to the DC and MB connection surfaces. In an alternative embodiment, a conductive elastomer is affixed to glue channels located about DC and MB pad-arrays and none affixed to either side of the 3D-SpaceX connector interface. In another example of embodiments, as illustrated in FIG. 2C, a 3D-SpaceX assembly 203 includes circular 3D-SpaceX connectors 230, 232 on opposite sides of DUT cutout 260. In an embodiment, conductive elastomers are stretched and glued over a circular frames 234 (opposing side frame not shown) then placed into circularly milled grooves on either side of each 3D-SpaceX connector to overlay opposing pad-array surfaces. Further as illustrated, each 3D-SpaceX connector 230, 232 has a different electrical arrangement. For example, 3D-SpaceX connector 230 has a pad-array field containing 1077 pins and 3D-SpaceX connector 232 has a pad-array field containing 1049 pins. Accordingly, it will be appreciated that embodiments can include any combination of physical and electrical arrangements for the 3D-SpaceX connectors.

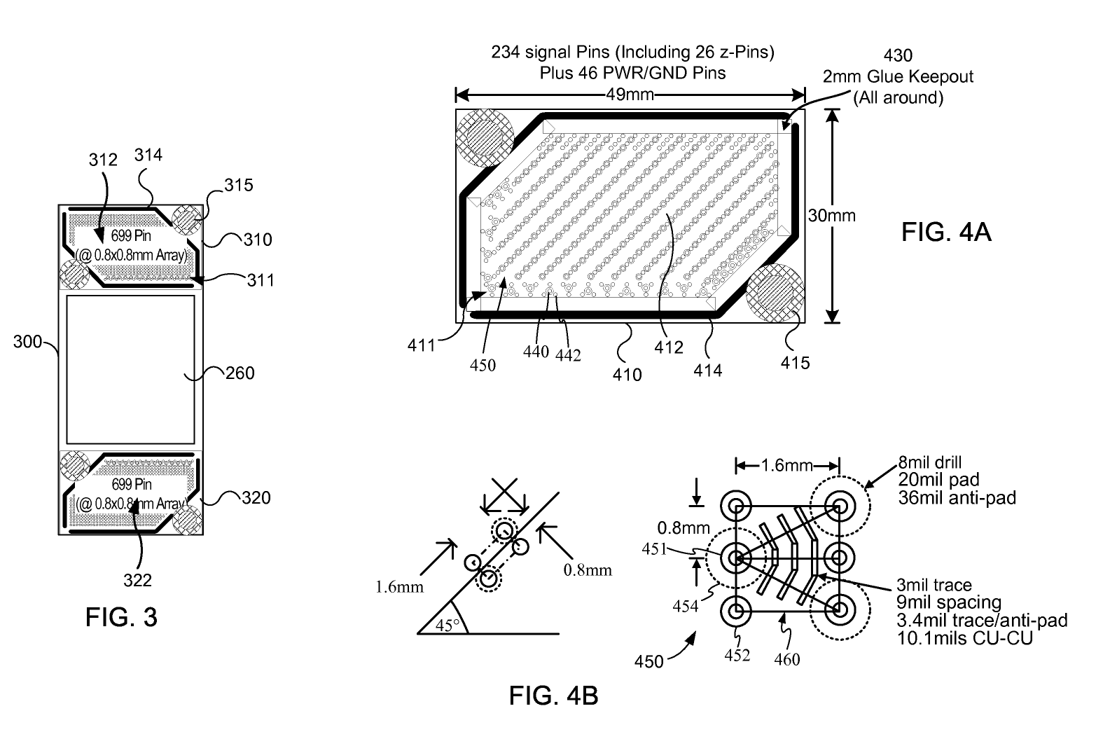

Referring to FIG. 3, another configuration of a 3D-SpaceX connector arrangement is illustrated. In this configuration a monolithic space transformer connector 300 has 3D-SpaceX connectors 310, 320 (connector portions) located on opposite sides of a DUT cutout area 260. 3D-SpaceX connectors 310, 320 have generally parallelogram shaped pad-array fields (e.g., 312, 322). However, the pad-array field arrangement for 3D-SpaceX connector 310, is the inverse (mirrored image) of the 3D-SpaceX connector 320. Additional aspects of the 3D-SpaceX connectors 310, 320 will be described in relationship to 3D-SpaceX connectors 310 only to avoid unnecessary repetition.

The pad-array field 312 of 3D-SpaceX connector 310 includes a plurality of high frequency/wideband pin connections 311. Additional details regarding the wideband pins will be discussed below. 3D-SpaceX connector 310 also includes glue channels 314 for holding down an elastomeric conductor which serves as the electrical coupling point for pad-array 312. Further, 3D-SpaceX connector 310 includes two coaxial mounts 315, which provide both alignment and mounting for 3D-SpaceX connector 310. The use of the term “coaxial mounts” herein is defined as the combination of DC, 3D-SpaceX, and MB PCB alignment and compressive mounting means provided along a common z-axis line perpendicular to the x-y plane of the PCB sandwich illustrated in FIG. 13 and discussion thereof below. This means holds the distinct advantage in the reduction of the number of PCB hardware clearance features required. Minimizing the number and size of these features significantly increases trace routing area and resultant trace density as well as affording ample trace isolation as needed.

FIG. 4A is a detailed illustration of a pad-array field arrangement of a 3D-SpaceX connector. Similar to the pad-array field described above in relation to FIG. 3, the 3D-SpaceX connector 410 includes a plurality of wideband pin connections 411. Additionally, the 3D-SpaceX connector 410 also includes glue channels 414 for holding down an elastomeric conductor. It will be appreciated, that a keepout region 430 can be provided adjacent the glue channels to prevent contamination of the contacts from the adhesive used to secure the conductive elastomer. In the example embodiment, a 2 mm region is provided around the entire pad-array. However, it will be appreciated that this example is merely provided for this illustration and the width and length of the keep-out region may be adjusted to accommodate the specific configuration of the pad-array and glue channels. Further, 3D-SpaceX connector 410 includes two coaxial mounts 415, which provide both alignment and mounting for 3D-SpaceX connector 410. Each coaxial mount 415 may be formed from a metal insert. Alternatively, coaxial mount 415 may be formed of a non-metal insert. Regardless of the configuration, coaxial mount 415 is configured to provide for a precise alignment interface to the adjacent elements (e.g., mother board and/or daughter card). For example, an insert used to form coaxial mount 415 may be machined, molded, etc. to achieve a precise internal dimension that can be used for alignment to adjacent elements (see, e.g., FIG. 13). Further, in configurations where it is desired to have compressive force applied internally, coaxial mount 415 may include an inner threaded element that allows for a smaller fastener to be inserted for purposes of supplying compressive force while a larger inner precision inner diameter of coaxial mount 415 can be used for alignment purposes. It will be appreciated that for standalone 3D-SpaceX connectors, both coaxial mounts are used for mounting and alignment. However, in other embodiments where two or more 3D-SpaceX connectors are part of a space transformer connector, only opposite end corner coaxial mounts may be used for alignment purposes. Once again, the mounting configuration is provided merely to illustrate aspects of the embodiments and the scope of the invention is not limited to any specific configuration illustrated.

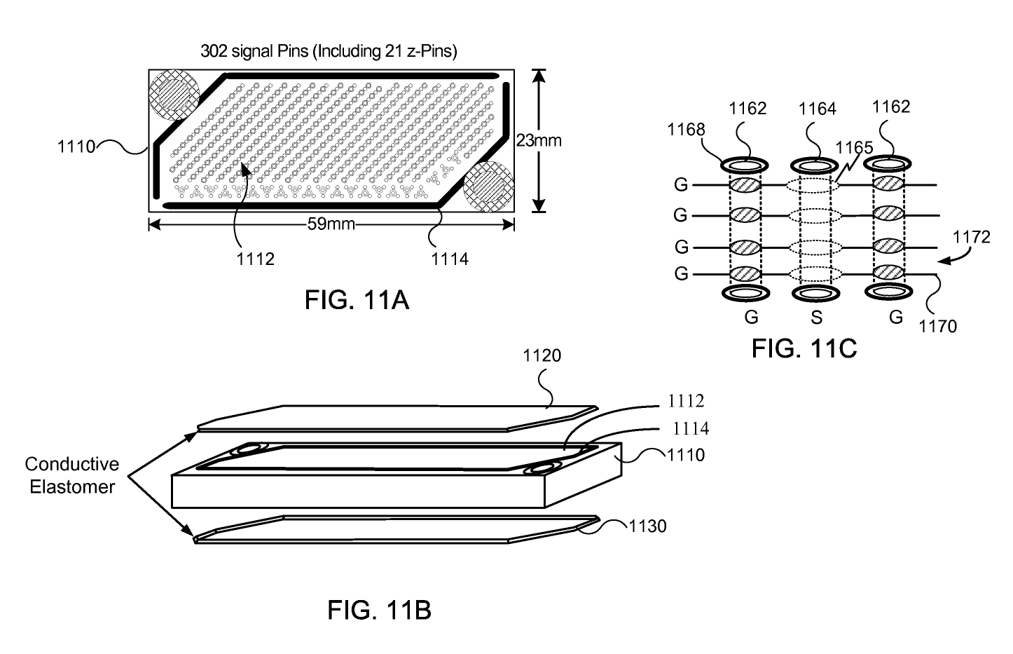

The ultra wideband contact pads/pins 411 are generally arranged to simulate a coaxial cable configuration. For example, pin 440 group configuration geometry can have one or more ground pins 442 adjacent the wideband signal pin 440. In the illustrated configuration, three ground pins 442 are placed symmetrically around the wideband pin 440. Additionally, wideband pin 440 can be configured to include an antipad. In one example, an antipad is an area where the dielectric copper cladding has been removed so there is no copper surrounding the signal via throughout all PCB inner layers. Embodiments may include any combination of signal and ground vias, via geometry, and one or more antipad characteristics. Accordingly, the wideband pins 411 can provide for minimal degradation of high frequency signals. Internal arrangements of the connector including the antipads are illustrated in relation to FIG. 11C.

FIG. 4B illustrates the details of other portions of the pad-array 412, where the contact pad (connected as signal pins or ground pins) are configured in a ground/signal/ground (GSG) configuration 450. For example, each/signal pin 451 is adjacent a ground pin 452 in rows 450. The signal pin 451 can also be configured inclusive of an antipad 454, as discussed above. Further, in another aspect, the arrangement of the signal and ground pins in adjacent rows can be alternated such that signal pins oppose ground pins. In this embodiment, signal bandwidth is maximized for a given PCB pad-array field construction. Further, rows 450 of pad-array field 412 may be oriented at an angle and separated at a distance to facilitate additional high density copper-to-copper (CU-CU) routing opportunities between daughter card DUT and 3D-SpaceX pad-array as with the three traces 460 routed between pad rows. The degree of row separation and inclination in relation to the PCB material mechanical and electrical characteristics relates to the number and width of adjacent traces allowable as detailed in FIG. 4B.

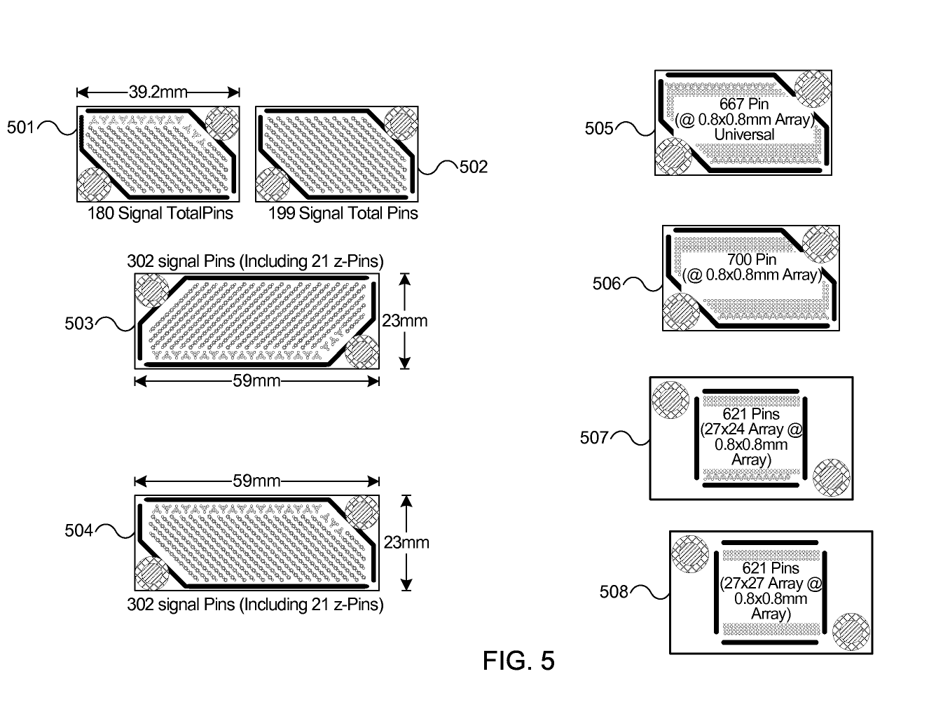

FIG. 5 illustrates a variety of space transformer connector pad-array field configurations. The example space transformer connectors illustrated have a variety of geometric pad-array fields, and mounting configurations and geometries such as square (508), rectangular (507), or trapezoidal (501-506). Pad-array field/contact pad placement includes regular (uniform) to random patterns with segmented and non-segmented pad-array group geometries not limited to circular, rectangular, square, trapezoidal, parallelogram, N-sided convex and concaved polygons, and free-form pad-array fields and the like. Accordingly, it will be appreciated that embodiments are not limited to any specific geometric pad-array field and mounting configuration and that the illustrated examples are provided merely for illustration of aspects and flexibility of the embodiments.

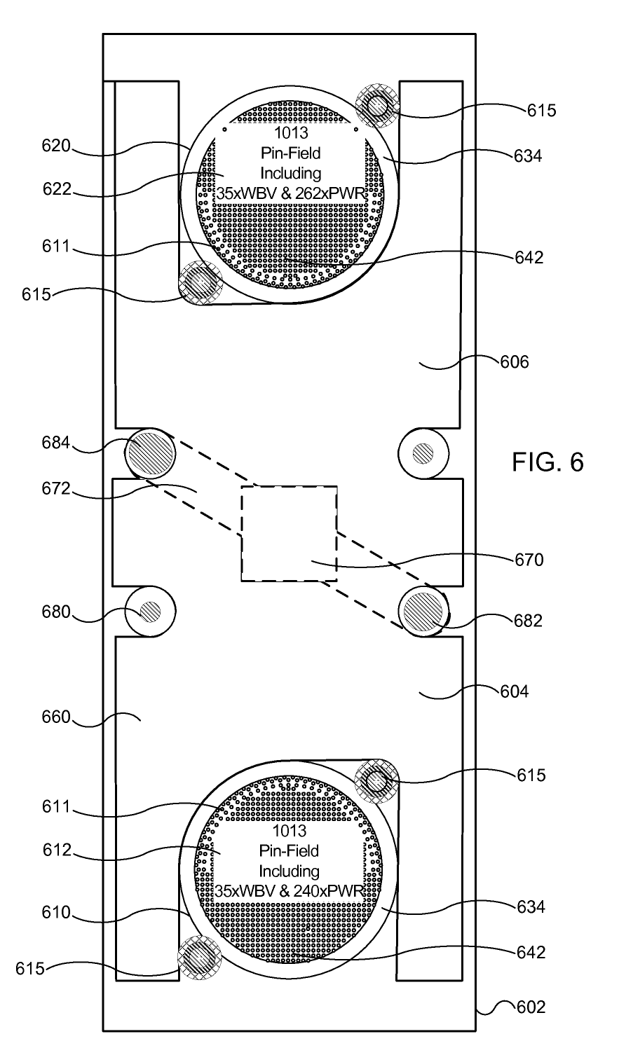

FIG. 6 illustrates two circular 3D-SpaceX connector portions 610 and 620 on a space transformer connector 602 formed from a monolithic PCB. Each connector portion is shown with two mounting and alignment features 615 oriented as in one embodiment. It will be appreciated that the embodiments are not limited to any specific mechanical alignment/mounting orientation. Pad-array fields 612 and 622 are shown oriented with wideband contact pads/pins 611 directed towards the center of the DUT area cutout 660 to facilitate short low loss DUT to MB signal connectivity. The pin-arrays 612 and 622, as shown, are in an arrangement of equidistant pad rows and columns but may be configured the same or uniquely as needed on an application specific basis. In an embodiment, DUT (and possibly DUT support circuit) direct current power (PWR) and ground (GND) connections 642 of 3D-SpaceX connectors 610 and 620 are shown for illustration in two locations within the each 3D-SpaceX connector as 16-PWR/GND supply inputs; in connector 610, directly opposite wideband pads 611 and in 620, directly behind wideband pads 611. Although locating PWR & GND pins in either of the two locations shown is an exemplary embodiment any location within the pad-array field is embodied as well as the increase, decrease, or elimination PWR/GND connections altogether. These examples and illustrations are provided solely to facilitate discussion and understanding of embodiments and are not to be construed as limiting embodiments. In the example embodiment of FIG. 6 conductive elastomers may optionally be stretched and glued over circular frames 634 then placed into circularly milled grooves on either side of each 3D-SpaceX connector PCB 602 to overlay opposing pad-array field surfaces. Milled grooves (not shown, but similar to 414, for example) can be made of a depth slightly exceeding elastomer frame thickness to ensure the co-planarity and requisite integrity of the 3D-SpaceX to DC/MB electro-mechanical interface.

In the embodiment of FIG. 6 the example of opposing locations of the two mounting and alignment coaxial mounts 615 may be oriented about the center of each 3D-SpaceX connector location on an application specific basis. Further, in applications for which the 3D-SpaceX mechanical mounting and alignment features must be fixed, for example across a given product line, the circular embodiment of the 3D-SpaceX connector pad-array field may be rotated about its axis to establish ideal wideband pin 611 ingress and egress with respect to corresponding DUT (and/or DUT support circuits) high speed signal placement.

Further, FIG. 6 illustrates a milled DUT cutout area 660 that may be relieved entirely of its board center material or optionally include a remote integrated mount 680, 682, 684 for mounting the space transformer 602, which is remotely locate relative to the coaxial connector mounts 615 and separated from connector mounts by removed portions 603 and 606. The remote integrated mount may also be used for mounting/coupling to other devices, for example, DUT socket mounting supports 680 (2-places), 682, 684 and optional DUT center pedestal support 670 for applications requiring DUT socket to MB (through DC and 3D-SpaceX PCB) attachment and DUT center support in certain automatic DUT handling applications. Additionally, the DUT center support may be configured to provide electrical shielding (e.g., by using metal layer in the PCB) between the DUT and top of the MB. DUT center support bridge 672 can also optionally be milled thin from either side or both to the point that the DUT center support remains mechanically integral to the space transformer connector 602, yet permits the extensive placement of DC bottom-side circuit components in close proximity to the DUT footprint or to better utilize MB top surface component placement.

FIG. 6 additionally illustrates extensive PCB milling, in addition to that within the DUT cutout area 660, immediately adjacent to (including around the sides of) 3D-SpaceX connectors (connector portions) 610 and 620. The advantage of this milling is two-fold; first, to improve co-planarity of mating surfaces and ensure an integral electro-mechanical connector interface and, second, to minimize “Skin Effect” trace signal loss in wideband signal routing. Although detached (free-standing) 3D-SpaceX connectors, when individually fabricated from differing PCB material lots and then applied in an application of two or more connectors are an embodiment of this invention, respective connectors may have differing overall thicknesses. When discrete 3D-SpaceX connectors are used in close proximity, differing connector thicknesses may compromise MB/3D-SpaceX/DC interface co-planarity. Fabricating two or more 3D-SpaceX connectors on a common monolithic PCB substrate effectively eliminates (i.e., significantly reduces) non co-planarity issues resulting from varying connector PCB thicknesses. In addition, the application of PCB milling such as to those shown in FIG. 6 effectively mechanically isolates each 3D-SpaceX connector allowing it to freely establish its own mechanical steady state position. Each connector is effectively independent of all others as well as from the integrated DUT socket mounting if utilized.

As is known to those skilled in the art, Skin Effect losses increase with decreased electrical conductor geometry and increased dielectric constant (greater than that of air) of trace adjacent insulators. Narrow impedance controlled traces sandwiched between PCB dielectric in stripline fashion have a higher skin effect loss than those of wide PCB surface microstrip traces of the same impedance. As such, bottom-side DC signal conductors configured as impedance controlled microstrip traces (wherein air is an adjacent trace dielectric) afford the most optimal signal handling characteristics attainable in a PCB environment. By milling out as much of the 3D-SpaceX PCB material as possible around each 3D-SpaceX connector, the amount of surface conductor for which air as a dielectric is maximized.

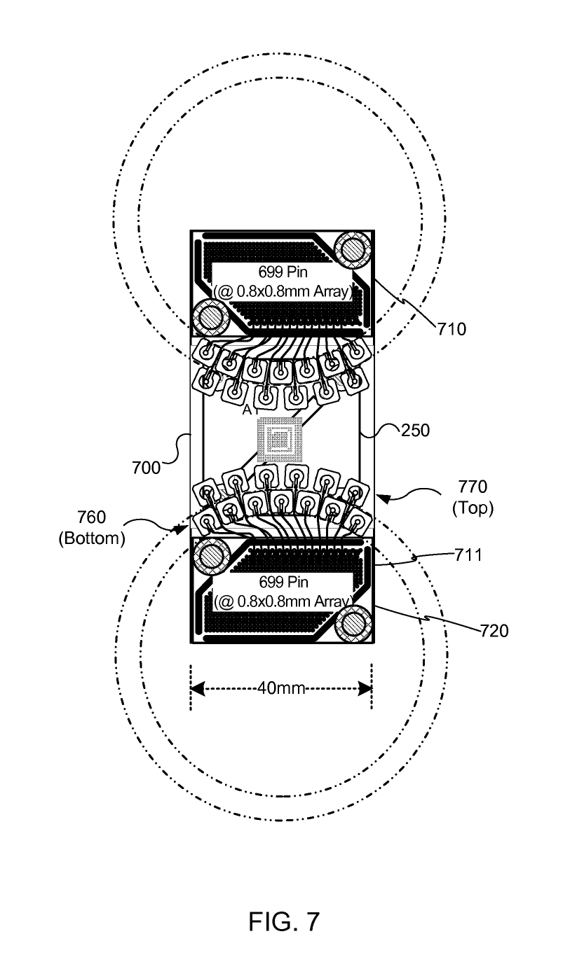

FIG. 7 illustrates a configuration of a daughter card footprint, superimposed over 3D-SpaceX 710, 720 connectors and motherboard with radio frequency (RF) connectors placed and trace-connected to the MB wideband pad-array pins. Only the MB RF connectors are illustrated in detail, however, it will be appreciated that the motherboard components and features (not shown) may include a variety of other elements, connectors, and the like. The daughter card 700 (footprint shown in the figure) contains a DUT 250, and 3D-SpaceX connector pin-fields, such as discussed in relation to the previous embodiments, accordingly common elements will not be recited or explained in detail. The wideband pins 711 can be configured to couple to wideband/high frequency connections to the motherboard which are coupled to the RF connectors 760 and 770, which are mounted on a bottom side and through to the bottom side from a top side of the motherboard, respectively. The RF connectors 760 and 770 are located on an arbitrary first and second radius and the RF connectors can be staggered from top to bottom in an alternating pattern (e.g., every other connector is on the top or bottom of the motherboard). Doing so improves adjacent wideband connection isolation. It will be noted that RF connectors placed along a radius about a circular 3D-SpaceX connector embodiment (e.g. 610, FIG. 6 and the like), afford ease of equal length transmission trace routing to a wideband pad-array field when required.

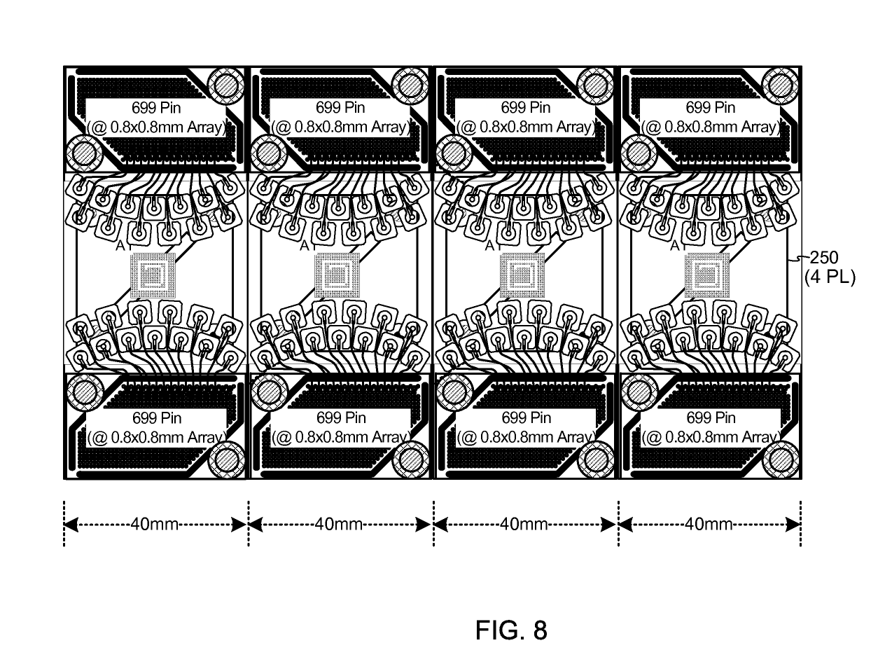

FIG. 8 illustrates an arrangement of four daughter card footprints superimposed over respective 3D-SpaceX connectors and individual motherboard locations having radio frequency (RF) connectors placed and trace connected to each MB wideband pad-array field. Each daughter card contains a DUT 250, and 3D-SpaceX connector pad-array field, such as discussed in relation to the previous embodiments. Accordingly, four DUTs can be tested in a compact form, as each daughter card and its associated RF connections are contained within a uniform profile (e.g., 40 mm by 90 mm as illustrated). Further, embodiments facilitate the support of multiple DUT rows (not shown) by the placement of two or more DUTs vertically and including one or more 3D-SpaceX connectors between them. Accordingly, embodiments include support for an array of DUTs in both the x and y dimensions.

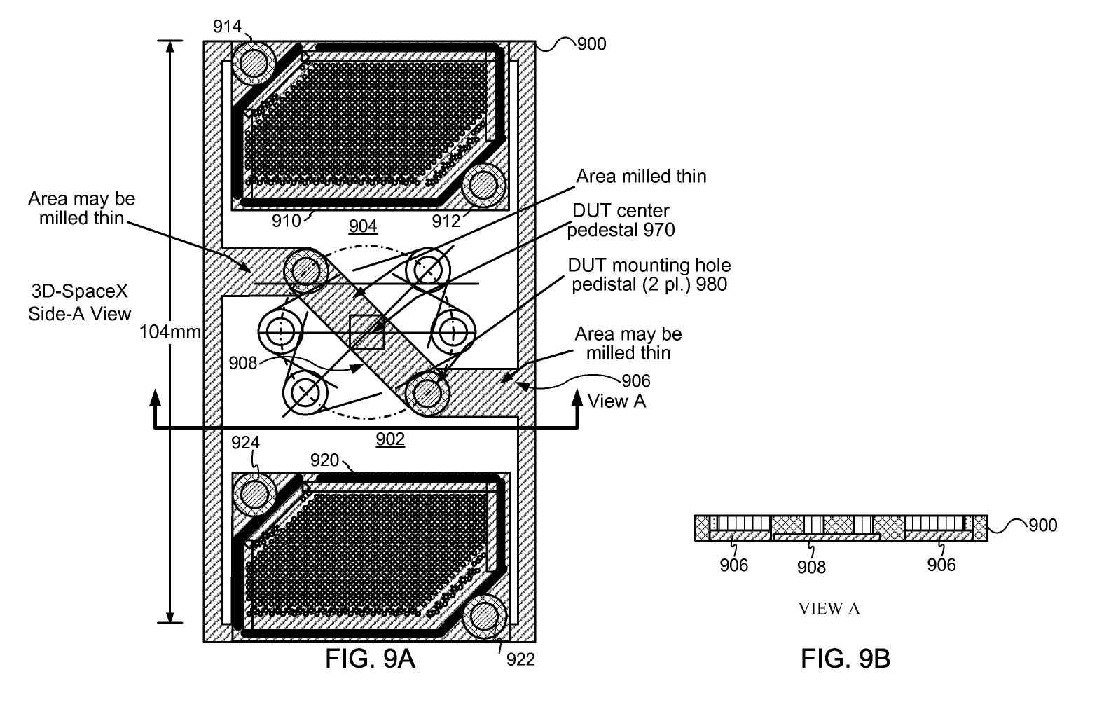

FIG. 9A illustrates two 3D-SpaceX connectors (connector portions) of a space transformer connector 900 formed of common PCB material and located on opposite ends of space transformer connector 900. As illustrated, space transformer connector 900 surfaces are co-planar and of uniform thickness under the two 3D-SpaceX pad-array fields, edge extremities, and optional integrated DUT mounting pads 980 and pedestal 970. The integrated DUT mounting pads 980 also form a remote integrated mount in relation to 3D-SpaceX connectors 910, 920 and may be used in various embodiments with or without the DUT pedestal and with one or more 3D-SpaceX connectors to provide a remote mounting location. The PCB material of space transformer connector 900 can be extended beyond the 3D-SpaceX connector portion and may be milled out (or otherwise have the material removed) in portions (e.g., 902 and 904) immediately adjacent to the 3D-SpaceX connectors 910, 920. Portions 902 and 904 that have all material removed, may substantially extend around the perimeter (e.g., three sides or at least half of the perimeter) of each 3D-SpaceX connector, so only a portion of the 3D-SpaceX connector is coupled to the remaining PCB material of space transformer connector 900.

Further, the remaining areas of space transformer connector 900 may be reduced in thickness for various portions. For example, 908 located under the DUT mounting area can be milled thinner than portions 906, outside the DUT mounting area. Using a configuration similar to that detailed in FIG. 6, for example, coaxial mounting points 912, 914 of the first 3D-SpaceX connector 910 form a mounting frame of reference about which the 3D-SpaceX connector 910 can independently physically locate (e.g., connector portion 910 is relatively free floating in relation to the remote integrated mount 980. Likewise, coaxial mounting points 922, 924 of the second 3D-SpaceX connector 920 form a separate mounting frame of reference about which the 3D-SpaceX connector 920 can locate effectively independent of the first connector 910. Accordingly, non co-planarity between the mounting surfaces (e.g., daughter card/motherboard) can be accommodated for by each of the 3D-SpaceX connectors 910, 920. Additionally, by allowing portions 902 and 904 to be open, conductive traces including pads (e.g., on the bottom of the daughter card) can get the approximate properties of micro-strip with air being the dielectric.

FIG. 9B illustrates an end view through section A of space transformer connector 900. As illustrated and discussed above, area 908 located under the DUT mounting is milled thinner than portions 906, outside the DUT mounting area. This reduced thickness under the DUT can provide spacing for surface mounted components on the daughter card and/or motherboard. Further, although only milled on one side as illustrated, it will be appreciated that either side or both sides can have material removed to provide a reduced thickness and clearance for adjacent DC/MB elements.

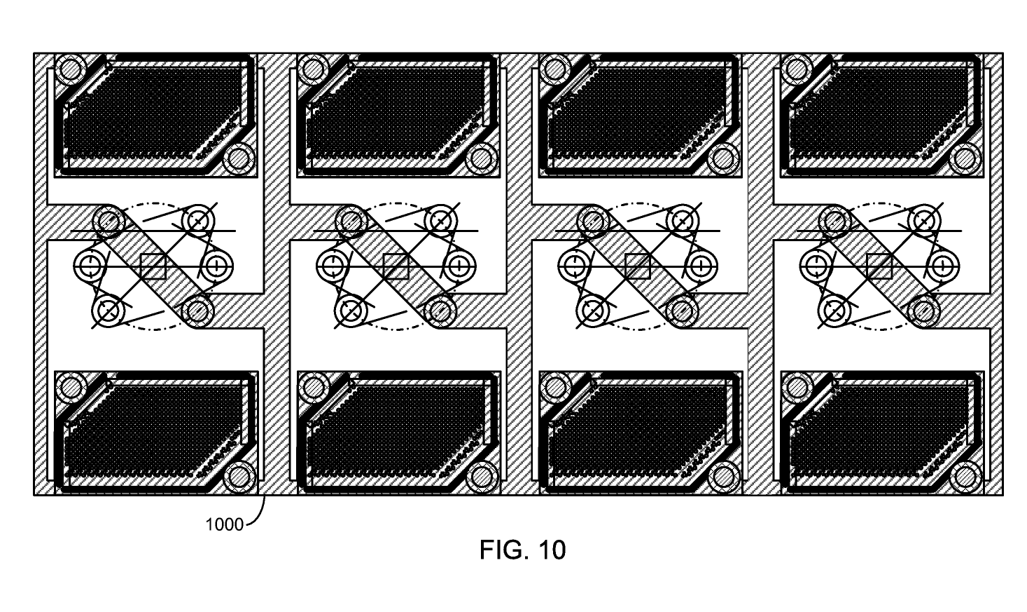

As noted above, two or more 3D-SpaceX connectors can be formed space transformer connector 1000 formed from a common circuit board (PCB). FIG. 10 illustrates an arrangement of multiple 3D-SpaceX connector pairs all fabricated from and located on a common circuit board of space transformer connector 1000. Since the 3D-SpaceX connectors are made from a common circuit board, the thickness of each of the 3D-SpaceX connectors can be controlled, which can help to mitigate variations due to 3D-SpaceX connectors being made from different circuit boards. However, it will be appreciated that the embodiments are not limited to the illustrations of FIGS. 9A and 10. For example, as discussed above, the number of 3D-SpaceX connectors and DUT locations may be expanded into a row/column array of DUTs. Alternatively, as illustrated in other embodiments each 3D-SpaceX connector can be formed on separate circuit boards.

Further, it can be appreciated that if each of the 3D-SpaceX connectors shown in FIG. 10 were configured as in the FIG. 6 circular connector embodiment, a circular pad-array field equal in area to the parallelogram connectors shown would afford a much greater connector to connector separation distance. For example, assigning each FIG. 10 connector pin-array a 3×2 cm x-y dimension (a 6 square-cm area) with pad-array field centers separated by 4 cm, the 3D-SpaceX edge to edge connector spacing would be 1 cm. Circular 3D-SpaceX connectors of 6 square-cm area each would yield a nearly 1.24 cm edge to edge separation. This additional separation distance greatly enhances MB routing area between 3D-SpaceX connectors. Once again it will be appreciated that pad-array field geometry and pin configurations are provided merely for illustration and that embodiments may interchangeably use the various pad-array field geometry and pin configurations as desired for a specific applications.

FIG. 11A illustrates a plan view of spacer transformer connector 1110 (embodied as a standalone 3D-SpaceX connector) illustrating the pad-array field 1112 and glue channels 1114 prior to the addition of a conductive elastomer. FIG. 11B is a perspective view of the 3D-SpaceX connector 1110 with top conductive elastomer 1120 and bottom conductive elastomer 1130 adjacent to the surfaces they are adhered to. For example, in assembling 3D-SpaceX connector 1110 top conductive elastomer 1120 can be stretched and secured to glue channel 1114, which provides for adhesion of conductive elastomer 1120 to ensure that pad-array field 1112 is uniformly covered by the conductive elastomer 1120. The bottom conductive elastomer 1130 can be secured to the bottom of 3D-SpaceX connector 1110 via similar glue channels, which are not illustrated. With attached elastomer coverings on either side of each 3D-SpaceX connector no separate framed elastomer piece-parts are required. Further, at least two of four mating surface interfaces (the contact pads in on pad-array field 1112) benefit by having the conductive elastomers 1120 and 1130 form integral pad-array field dust covers on the top and bottom pad-array fields 1112.

FIG. 11C illustrates a sectional view of a portion of the 3D-SpaceX connector 1110. In one embodiment, the 3D-SpaceX connector can be made up of a multilayered PCB having a plurality of ground planes 1170 separated by layers of dielectric material 1172. Further, additional conductive planes/traces may be included internally separated by dielectric layers for routing signals internally. Conductive ground vias 1162 and signal vias 1164 can run substantially perpendicular to the ground planes 1170. Each via is connected to contact pads 1168 affixed to it at each PCB surface. The ground vias 1162 can be coupled to the ground planes, whereas the signal vias 1164 may have antipads 1165 formed in each ground plane. This arrangement provides for coaxial-type performance to contain the electrical fields of the signal vias 1164. Further it will be appreciated that in various embodiments a first contact pad may be coupled to a conductive via that may extend only partially through the PCB to an internal connection point and may be routed from there to one or more conductive vias that couple to one or more pads that may be physically offset from the first contact pad. Accordingly, embodiments include configurations where the coupled contact pads on either side of the space transformer connector 1110, may be physically offset from each other.

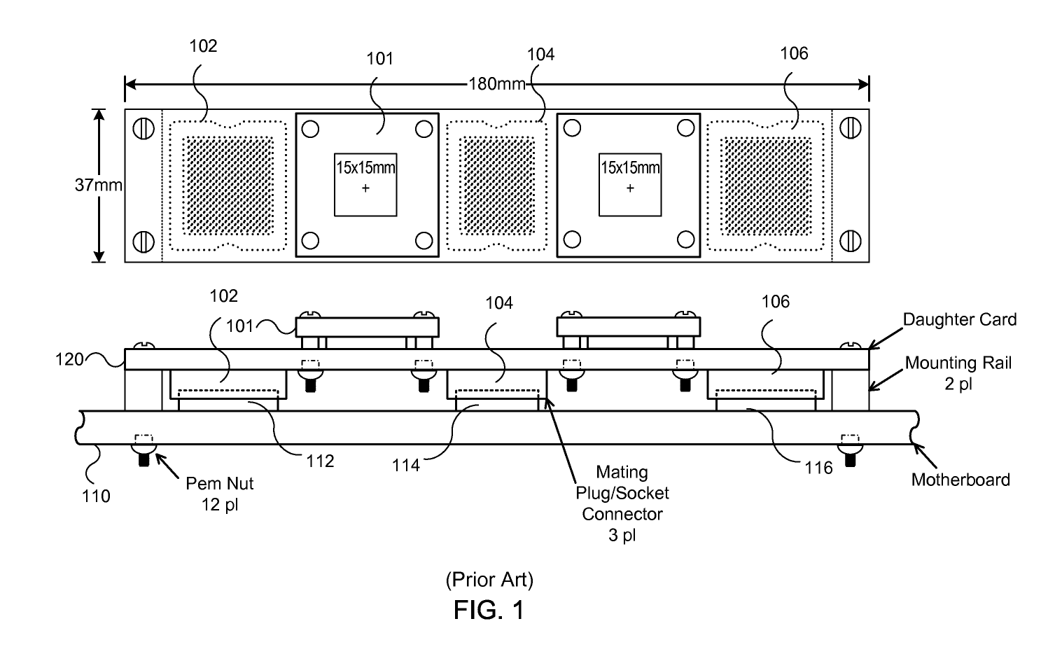

The conductive elastomer 1120, 1130 provides for a contact between the pad-array field and electrical connections on a mating surface (e.g., bottom of daughter card). For example, when the daughter card, space transformer connector 1170, and MB are mechanically coupled together the pressure of the clamping force allows for the connection from the pad-array field 1112 to contact both the contacts on the daughter card and motherboard, without the need of any permanent connections (e.g., soldering) or bulky/complex electro-mechanical connection, such as in the plug and socket configuration of FIG. 1. The conductive elastomer may be in a sheet form, a spray-on material, or any other similar high density conductive compressible material, that becomes conductive in vertical paths under pressure.

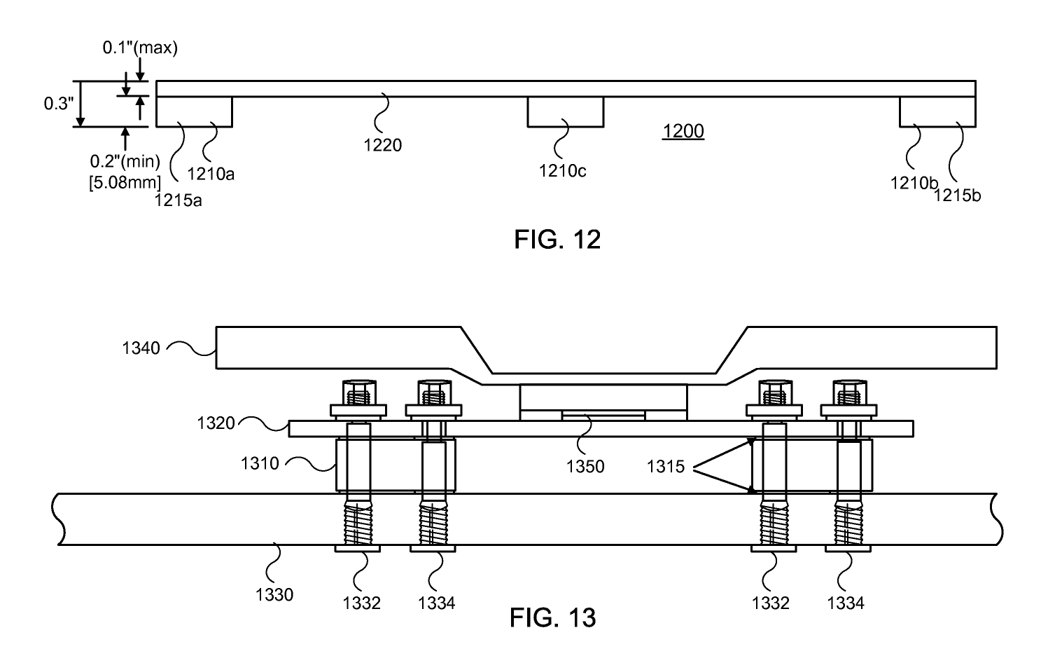

FIG. 12 illustrates an embodiment where a daughter card 1220 and 3D-SpaceX connector portions 1210a-c are integral being formed from a common PCB of space transformer connector 1200. In this configuration there would be no need for a conductive elastomer between the integrated daughter card 1220 and 3D-SpaceX connectors 1210a-c, as they would already be a single entity. Accordingly, a conductive elastomer with glue channel or other type of conductive medium and its requisite support structure(s) as necessary would be used on the surfaces of the 3D-SpaceX connectors 1210a-c that are opposite the daughter card portion 1220. Each connector portions 1210a-c has a pad-array field having a plurality of contact pads which are coupled to conductive vias. The connectors 1210a-c comprises a plurality of ground planes separated by layers of dielectric material in the PCB as in the other spacer connector embodiments. However, the PCB material extends beyond the connectors 1210a-c and includes layers forming the daughter card 1220. Coaxial mounts (1215a, b) can be provided at opposite ends for alignment and mounting. Each coaxial mount 1215a, 1215b can be located adjacent the pad-array field of respective connector portions 1210a, 1210b. Once again, the dimensions in the illustrated example are provided to aid an appreciation of the scale in one example and are not to be construed as limiting the scope of the embodiments.

Conventional configurations have utilized two discrete pin-field alignment means and four or more compressive mounting points per connector (see, e.g., FIG. 2A). Embodiments of the space transformer connector include variants of which are based on a monolithic PCB construction or formed of one or more individual free-standing (discrete) PCB connector(s) (3D-SpaceX connectors). Each may use as few as two compressive mounting points per pin-field as dictated by the pin-array group geometry. In the monolithic PCB spacer transformer connector configurations, the “linked” pad-array fields (see, e.g., FIGS. 2B-C, and 7) is suitable for applications in which moderately co-planar daughter card and mother board PCB surfaces are present. For two-connector linked pad-array fields spacer transformer connectors, only one combined mounting/alignment point is required per connector portion (adjacent the pad-array field) and may be located at opposite corners of the extreme ends of the monolithic spacer transformer connector PCB. In the case of three or more linked-pin-field connectors per spacer transformer connector PCB (e.g., FIG. 12), again only the two opposing maximally separated mounting points may be fashioned with integral alignment features (e.g., coaxial mount 415). Additional integral intra PCB connector linked-pin-field location(s) can be provisioned with a pair of daughter card/3D-SpaceX connector only alignment features along with mother board/daughter card/3D-SpaceX connector compressive retainers.

The “floater” pad-array field/connector portions configuration (see, e.g., FIGS. 6 and 9A) is suited for applications in which the mother board and/or daughter card surface co-planarity is suboptimal. With essentially free-floating pad-array field/connector portions (but loosely coupled by space transformer connector PCB), the floater configuration of the 3D-SpaceX connectors utilize two mother board/daughter card/3D-SpaceX mounting and alignment combined points (e.g., coaxial mounts 415) within each connector portion irrespective of the number of connectors per space transformer connector PCB. Lastly, discrete space transformer connectors (stand alone 3D-SpaceX connectors) afford advantages similar to the floater pin-field connector but may be less expensive to fabricate. Also, discrete connectors of differing fabrication may be used within the same application for specialized signal transmission, current carrying characteristics and the like. Applications utilizing this discrete connector type should consider individual 3D-SpaceX connector PCB thickness variations when anticipating overall system mechanical tolerance limits.

FIG. 13 illustrates an example of a test assembly including space transformer connectors 1310 in a free-standing (discrete) configuration (e.g., standalone 3D-SpaceX connectors). As will be appreciated, 3D-SpaceX connectors 1310 including the conductive compressible medium 1315 (on both daughter card and mother board side of 3D-SpaceX connectors 1310) allow for repetitive coupling and decoupling of electrical connections with high signal integrity, which is well suited for integrated circuit (IC) testing assemblies among other applications. In the configuration illustrated, the 3D-SpaceX connectors 1310 provide the interface between daughter card 1320 and motherboard 1330. The assembly of the 3D-SpaceX connectors 1310, daughter card 1320 and motherboard 1330 can be mechanically coupled using a coaxial mounting and alignment arrangement as illustrated. For example, fasteners 1332 and 1334 may provided compressive force for the assembly and may also be used for alignment purposes between the mother board 1330 and the 3D-SpaceX connectors 1310 via the coaxial mounts. At the daughter card 1320 interface fastener 1332 provides for alignment while the reduced diameter portion of 1334 provides for compressive force without a strict alignment interface. It will be appreciated that the mounting means depicted is for illustration purposes only. Any number of methods may be utilized to provide requisite compressive force across the 3D-SpaceX connector interface. Additionally, as illustrated in FIG. 13, a test adapter mechanism 1340 can be used in combination with device-under-test socket and carrier (DUT) 1350 to rapidly load and test ICs, as is known in the art.

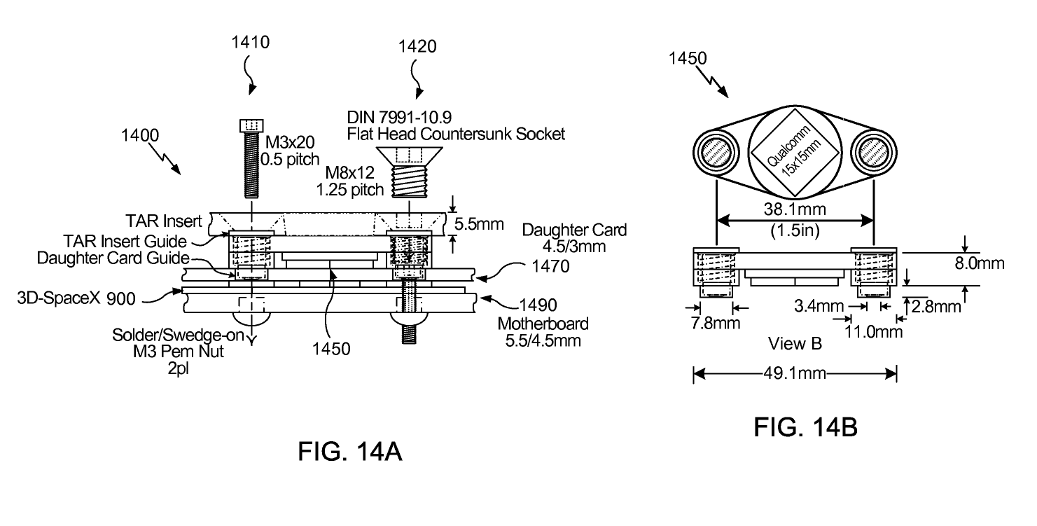

As was mentioned in the foregoing, and illustrated in some of the examples, embodiments can include coaxial mounting configurations to reduce the number of mechanical connections between the socket mount/DUT 1450, daughter card 1470, space transformer connector 900 and motherboard 1490. FIG. 14A is an illustration of an assembly including a partial illustration of space transformer connector 900 (e.g., as illustrated in FIG. 9A) and coaxial mounting assemblies 1410 and 1420, which can be used to secure the assembly 1400 including socket mount 1450, which is further illustrated in FIG. 14B. Details regarding the coaxial mount and socket are provided in U.S. patent application Ser. No. 12/543,373, entitled “Two-Mount and Three-Mount Socket Design with Coaxial Attachment and Alignment” filed Aug. 18, 2009, and assigned to the assignee hereof and hereby expressly incorporated by reference herein.

Accordingly, in view of the foregoing it will be appreciated that embodiments can include assemblies (e.g., as illustrated in FIGS. 13 and 14) including a daughter card (1320, 1470) coupled to a device-under-test (DUT) (1380, 1450) configured to distribute signals from the DUT to a first contact array to a mother board (1330, 1490) having a second contact array via a space transformer connector (1310, 900). The space transformer connector (1310, 900) can be formed of a multilayer printed circuit board (PCB) having a connector portion, as described in the foregoing embodiments.

For example, the connector portion (1310, 910, 920), can include a plurality of ground planes separated by layers of dielectric material in the PCB. A first pad-array field (e.g., top side of connector portions 910, 920) can have a plurality of contact pads located on a first surface of the PCB configured to couple to the first contact array of the daughter card and a second pad-array field (e.g., bottom side of connector portions 910, 920) can have a plurality of contact pads located on a second surface of the PCB configured to couple to the second contact array on the mother board (1330, 1490). The connector portions (910, 920) can further include a plurality of conductive vias (e.g., as illustrated in FIG. 11C) extending at least partially through the PCB to couple the first and second pad-array fields and at least one coaxial mount (e.g., 912, 922) for alignment and mounting located adjacent the first and second pad-array fields. A first conductive elastomer (e.g., 1315, 1120) can be disposed over the first pad-array field to electrically couple the first pad-array field to the first contact array. A second conductive elastomer (e.g., 1315, 1130) can be disposed over the second pad-array field to electrically couple the second pad-array field to the second contact array.

It will be appreciated that the various pad-array field configurations and space transformer connector configurations (e.g., linked, floater, discrete) may be used in circuit board assemblies and the discussions and illustrations provided herein are not intended to limit the embodiments. For example, the two-mount socket (e.g., 1450) assembly of FIG. 14 can be combined with a space transformer connector of FIG. 9 including an integrated mount portion formed from the PCB (980) configured to couple and align with the two coaxial mounts of the two-mount socket (1410, 1420). Further, the various features of the space transformer connectors discussed herein may be advantageously employed in various assemblies. For example, a portion of the PCB (902, 904) can removed from an area between the connector portion and the integrated mount portion (980) to mechanically isolate the connector portions (910, 920) from the DUT/socket mount location to achieve a relatively independent mechanical steady state position in relation to the integrated mount portion (980) adjacent DUT support pedestal (970). Further, as discussed in relation to FIG. 9, the DUT support pedestal (970) can have PCB material milled away adjacent the DUT support pedestal to allow for placement of electrical components adjacent the DUT pedestal and/or the DUT support pedestal (970) can be configured to provide electrical shielding. Once again, embodiments are not limited to the discussed or illustrated combinations and one skilled in the art will appreciate the interchangeability and application of the various embodiments of space transformer connectors disclosed herein.

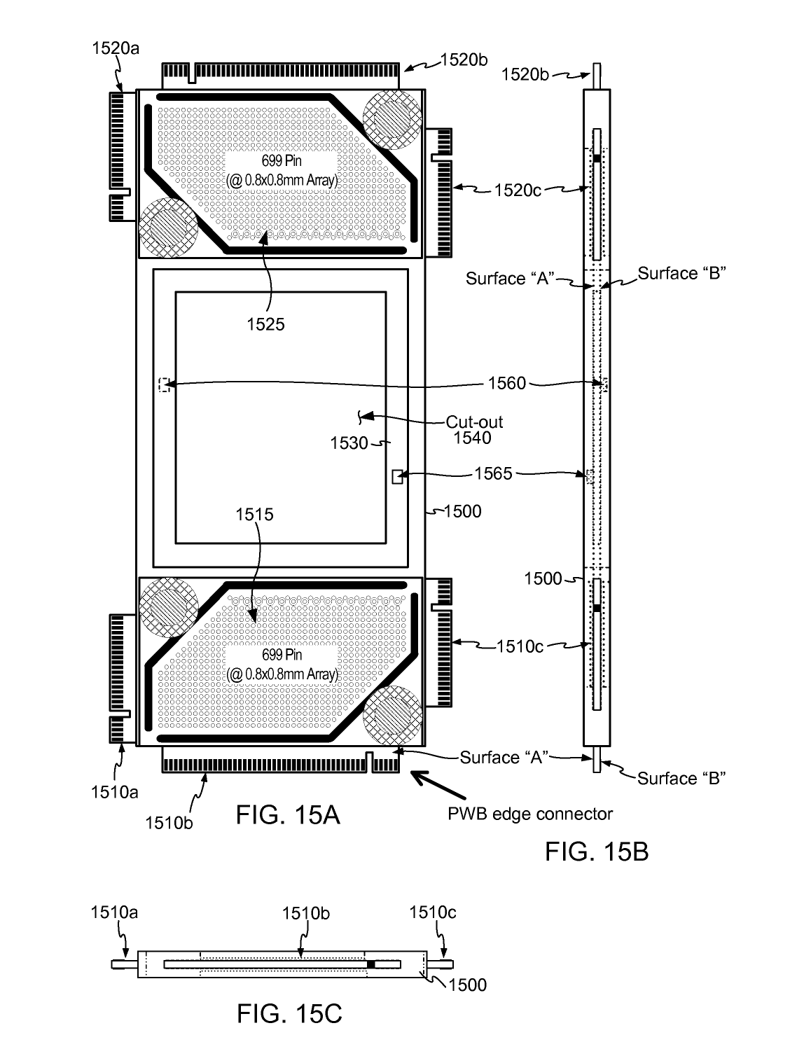

In further embodiment, FIGS. 15A-C illustrate a configuration of the spacer transformer connector 1500 having at least one PCB edge connector (e.g., 1510a-c, 1520a-c) to permit external connections to selected signals passing between the daughter card and the mother board. Referring to FIGS. 15A-C in addition to edge connectors 1510a-c and 1520a-c, a shelf 1530 may be formed to support the addition of one or more active/passive components (e.g., 1560 and 1565) directly coupled to the PCB forming the space transformer connector. The components 1560 and 1565 in embodiments may be located on either side of the shelf portion 1530. The active/passive components can be used for integral signal band limiting/shaping functions and may be comprised of lumped and/or distributed elements.

In some embodiments the shelf 1530 may be formed from the same portion that is used for the edge connectors 1510a-c and 1520a-c. A cut-out portion 1540 can be provided, for example, to facilitate cabling and mounting flexibility of the space transformer connector 1500. FIG. 15A illustrates three edge connectors 1510a-c adjacent pin-array field 1515 and three edge connectors 1520a-c adjacent pin-array field 1525. FIGS. 15B and 15C illustrate side and end views of the edge connector configuration, respectively. It will be appreciated that the number and location of edge connectors may be varied and the illustrated embodiment is not intended to limit various disclosed and claimed embodiments. Further, the edge connectors may be made of similar materials as the PCB in some embodiments or may be flexible circuit ribbon in other embodiments or combinations thereof. The remaining aspects of the spacer transformer connector 1500 are similar to the previously disclosed embodiments. Accordingly, a detailed description will not be provided herein.

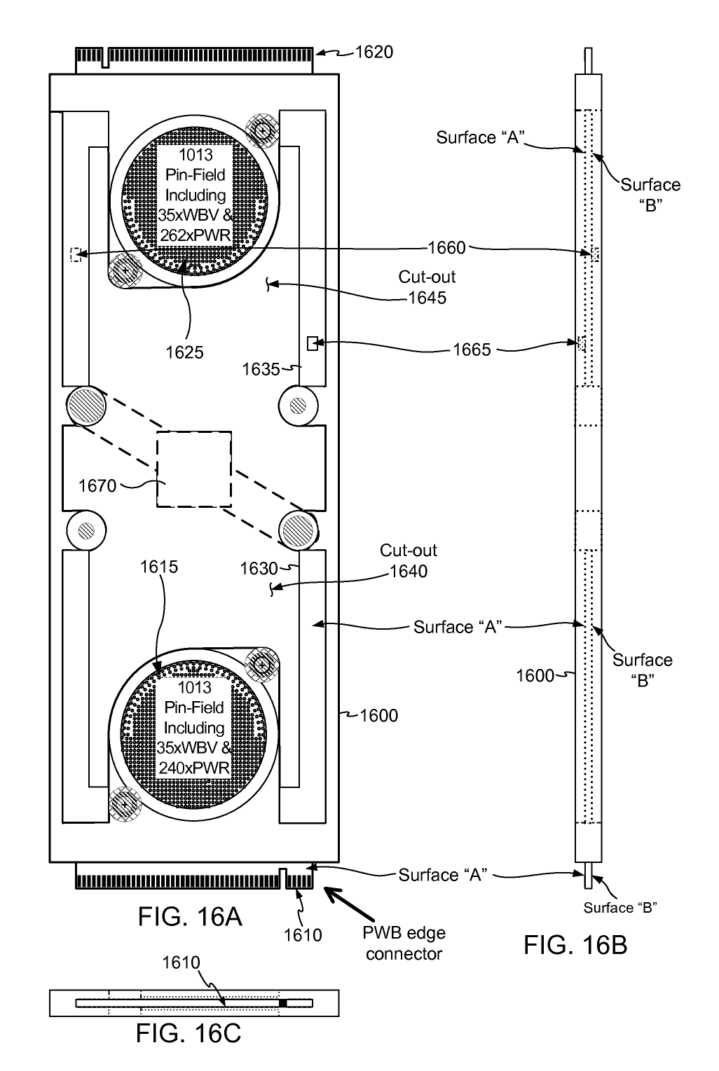

FIGS. 16A-C illustrate another configuration of the spacer transformer connector 1600 having at least one PCB edge connector (1610, 1620) to permit external connections to selected signals passing between the daughter card and the mother board. Referring to FIGS. 16A-C in addition to edge connectors 1610 and 1620, one or more shelf portions (e.g., 1630 and 1635) may be formed to support the addition of one or more active/passive components (e.g., 1660 and 1665) directly coupled to the PCB forming the space transformer connector. The components 1660 and 1665 in embodiments may be located on either side of the shelf portions 1630 and 1635. In some embodiments the shelf portions 1630 and 1635 may be formed from the same portion that used for the edge connectors 1610 and 1620. Cut-out portions 1640 and 1645 can be provided, for example, to facilitate cabling and mounting flexibility of the space transformer connector 1600. A pedestal 1670 may be provided between cutout portions 1640 and 1645 to aid in supporting a DUT. Further, depending on the configuration pedestal 1670 may retain one or more conductive layers formed from a portion of the same PCB forming the spacer transformer connector 1600. The one or more retained conductive layers may be used for various purposes such as routing signals and/or electromagnetic shielding.

FIG. 16A illustrates one edge connector 1610 adjacent circular pin-array field 1615 and an edge connector 1620 adjacent circular pin-array field 1625. FIGS. 16B and 16C illustrate side and end views of the edge connector configuration, respectively. Once again, it will be appreciated that number and location of edge connectors may be varied and the illustrated embodiment is not intended to limit various disclosed and claimed embodiments. Further, the edge connectors may be made of similar materials as the PCB in some embodiments or may be flexible circuit ribbon in other embodiments or combinations thereof. The remaining aspects of the spacer transformer connector 1600 are similar to the previously disclosed embodiments. Accordingly, a detailed description will not be provided herein.

It will be appreciated that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

It will be appreciated that space transformer connector, as discussed and illustrated in the foregoing disclosure and related figures, may be included within a daughter card/mother board assembly, an integrated circuit test system a or any other device that interfaces two high density contact arrays. Accordingly, embodiments of the disclosure may be suitably employed in any device which includes a space transformer connector as disclosed herein.

The foregoing disclosed devices and methods may be designed and configured into GDSII and GERBER computer files, stored on a computer readable media. These files are in turn provided to fabrication handlers who fabricate devices based on these files.

Accordingly, embodiments can include machine-readable media or computer-readable media embodying instructions which when executed by a processor transform the processor and any other cooperating elements into a machine for fabricating the embodiments described herein as provided for by the instructions.

While the foregoing disclosure shows illustrative embodiments, it should be noted that various changes and modifications could be made herein without departing from the scope of the invention as defined by the appended claims. For example, the various embodiments disclosed have illustrated relatively straight through coupling of signals from pads on a first side through the vias to corresponding pads on a second side. However, it will be appreciated that the multi-layer PCB construction allows for internal routing of signals (e.g., using blind and/or buried vias) so the correspondence between pads on the first side may be changed both in geometry (e.g., located in different relative positions) and number (e.g., one pad to two or more pads). Still further, the capacitive and/or inductive AC coupling across a 3D-SpaceX connector is possible by exploiting the flexibility of the 3D-SpaceX pad-array field and multi-layer PCB construction.

The functions, steps and/or actions of the method claims or describe in the disclosure in accordance with the embodiments described herein need not be performed in any particular order. Furthermore, although elements of the embodiments may be described or claimed in the singular, the plural is contemplated unless limitation to the singular is explicitly stated.

What is claimed is:

1. A space transformer connector formed of a multilayer printed circuit board (PCB) comprising:
a plurality of ground planes separated by layers of dielectric material in the PCB;
a plurality of conductive vias extending at least partially through the PCB;
a pad-array field having a plurality of contact pads located on opposing surfaces of the PCB, which are coupled to the conductive vias; and
at least one coaxial mount for alignment and mounting, wherein the coaxial mount is located adjacent the pad-array field.

2. The space transformer connector of claim 1, further comprising:
a remote integrated mount formed from the PCB, wherein at least a portion of the PCB is removed from an area between the pad-array field and the integrated mount.

3. The space transformer connector of claim 2, wherein the portion of PCB removed includes material around at least one-half of a perimeter of the pad-array field.

4. The space transformer connector of claim 2, wherein the portion of the PCB removed is configured to mechanically isolate the pad-array field to enable the pad-array field to achieve an independent mechanical steady state position.

5. The space transformer connector of claim 1, wherein at least one of the pad and conductive via structures is configured for high frequency.

6. The space transformer connector of claim 5, wherein ground and signal pads in adjacent rows can be alternated such that the signal pads oppose ground pads.

7. The space transformer connector of claim 5, wherein ground and signal pads are oriented at an angle and separated a distance to facilitate high density routing.

8. The space transformer connector of claim 7, wherein a degree of row separation and inclination relates to a number and width of adjacent traces allowable for given PCB mechanical and electrical characteristics.

9. The space transformer connector of claim 5, wherein the pad-array field is circular and wideband pads are located on a common radius to allow for equal length transmission trace routing to RF connectors.

10. The space transformer connector of claim 5, wherein ground vias are coupled to the ground planes and signal vias have antipads formed in each ground plane.

11. The space transformer connector of claim 5, wherein ground vias are coupled to the ground planes and coupled to pads that are arranged immediately adjacent to each other in at least one row for at least a portion of the row.

12. The space transformer connector of claim 1, wherein the pad-array fields are configured in at least one of a symmetrical physical arrangement or a non-symmetrical physical arrangement.

13. The space transformer connector of claim 1, further comprising:
a second pad-array located at an opposite end of the PCB from the pad-array field.

14. The space transformer connector of claim 13, wherein each pad-array field is one of circular, square, rectangular, or trapezoidal.

15. The space transformer connector of claim 14, wherein each pad-array field is circular and one is rotated about its axis with respect to the other, to facilitate ingress and egress of signals.

16. The space transformer connector of claim 13, wherein each pad-array field has an inverse configuration of the other pad-array field.

17. The space transformer connector of claim 13, wherein there are at least two coaxial mount per pad-array field.

18. The space transformer connector of claim 13, wherein at least a portion of the PCB is removed from an area between the pad-array fields.

19. The space transformer connector of claim 1, further comprising:
an integrated mount formed from the PCB, wherein at least a portion of the PCB is removed from an area between the pad-array field and the integrated mount; and
a device-under-test DUT support pedestal located adjacent to at least one integrated mount position.

20. The space transformer connector of claim 19, wherein the DUT support pedestal has PCB material milled away adjacent the DUT support pedestal.

21. The space transformer connector of claim 1, further comprising:
glue channels adjacent the pad-array field configured to mechanically attach a conductive elastomer.

22. The space transformer connector of claim 21, further comprising:
a keepout region between the glue channels and the pad-array field.

23. The space transformer connector of claim 21, wherein the glue channels are formed from grooves in the PCB material.

24. The space transformer connector of claim 1, wherein the space transformer connector is positioned between a daughter card and a mother board.

25. The space transformer connector of claim 24, wherein the pad-array field is arranged to match contacts of least one of the daughter card or the mother board.

26. The space transformer connector of claim 25, further comprising:
a conductive elastomer disposed over the pad-array field and configured to electrically couple the pad-array field to the contacts of at least one of the daughter card or the mother board.

27. The space transformer connector of claim 26, wherein the conductive elastomer becomes conductive under a range of pressures.

28. The space transformer connector of claim 1, further comprising:
at least one edge connector located adjacent pad-array field.

29. The space transformer connector of claim 28, wherein the PCB is includes a plurality of PCB layers and wherein the edge connector is formed from one at least one of the PCB layers.

30. The space transformer connector of claim 29, wherein a layer forming the edge connector also forms a shelf portion in an opening formed by the portion of the PCB removed.

31. The space transformer connector of claim 30, further comprising:
at least one active or passive component located on the shelf portion.

32. The space transformer connector of claim 28, wherein the edge connector is located approximately in the middle of the PCB layers.

33. The space transformer connector of claim 1, further comprising:
a shelf portion formed in an opening, wherein the shelf portion is formed by at least one layer of the PCB.

34. The space transformer connector of claim 33, further comprising:
at least one active or passive component located on the shelf portion.

35. The space transformer connector of claim 1, wherein at least one of the pads on one surface is coupled to at least two pads on the other surface.

36. The space transformer connector of claim 1, wherein at least one of the pads on one surface is coupled to a pad on the other surface that is located in a different relative position.

37. The space transformer connector of claim 1, wherein the PCB comprises:
a daughter card formed from a plurality of conductive planes separated by layers of dielectric material in the PCB that extend beyond the connector.

38. The space transformer connector of claim 37, further comprising:
a second connector portion having a pad-array field having a plurality of contact pads located on a second end of the PCB, which are coupled to conductive vias, wherein the PCB comprises a plurality of ground planes separated by layers of dielectric material in the PCB, which extends beyond the layers forming the daughter card; and
a second coaxial mount for alignment and mounting, wherein the second coaxial mount is located adjacent the second pad-array field.

39. An assembly comprising:
a daughter card coupled to a device-under-test (DUT) configured to distribute signals from the DUT to a first contact array;
a mother board having a second contact array;
a space transformer connector formed of a multilayer printed circuit board (PCB) having a connector portion comprising:
a plurality of ground planes separated by layers of dielectric material in the PCB;
a first pad-array field having a plurality of contact pads located on a first surface of the PCB configured to couple to the first contact array;
a second pad-array field having a plurality of contact pads located on a second surface of the PCB configured to couple to the second contact array;
a plurality of conductive vias extending at least partially through the PCB to couple the first and second pad-array fields; and
at least one coaxial mount for alignment and mounting, wherein the coaxial mount is located adjacent the first and second pad-array fields;
a first conductive elastomer disposed over the first pad-array field, wherein the first conductive elastomer is configured to electrically couple the first pad-array field to the first contact array; and
a second conductive elastomer disposed over the second pad-array field, wherein the second conductive elastomer is configured to electrically couple the second pad-array field to the second contact array.

40. The assembly of claim 39 further comprising:
a two-mount socket having two coaxial mounts for alignment and mounting, wherein the socket is configured to accept the device-under-test (DUT) and is coupled to the daughter card via the two coaxial mounts.

41. The assembly of claim 39, wherein the space transformer connector further comprises:
an integrated mount portion formed from the PCB and configured to couple and align with the two coaxial mounts of the two-mount socket, wherein at least a portion of the PCB is removed from an area between the connector portion and the integrated mount portion.

42. The assembly of claim 41, wherein the portion of the PCB removed is configured to mechanically isolate the connector portion to achieve an independent mechanical steady state position relative to the integrated mount portion.

43. The assembly of claim 42, wherein the portion of PCB removed includes material around at least one-half of a perimeter of the connector portion.

44. The assembly of claim 41, further comprising:
a DUT support pedestal located adjacent to the integrated mount portion.

45. The assembly of claim 44, wherein the DUT support pedestal has PCB material milled away adjacent the DUT support pedestal to allow for placement of electrical components adjacent the DUT pedestal.

46. The assembly of claim 44, wherein the DUT support pedestal is configured to provide electrical shielding.

47. A space transformer connector formed of a multilayer printed circuit board (PCB) comprising:
means for providing ground connections separated by layers of dielectric a dielectric means in the PCB;
means for providing electrical conductivity extending at least partially through the PCB;
means for providing electrical contact having a plurality of contact pads located on opposing surfaces of the PCB, which are coupled to the means for providing electrical conductivity; and
means for aligning and mounting in an integrated unit, wherein the means for aligning and mounting is located adjacent means for providing electrical contact.

48. The space transformer connector of claim 47, further comprising:
remote means for mounting formed from the PCB, wherein at least a portion of the PCB is removed from an area between the means for providing electrical contact and the remote means for mounting.

49. The space transformer connector of claim 48, wherein the portion of PCB removed includes material around at least one-half of a perimeter of the means for providing electrical contact to mechanically isolate the means for providing electrical contact to achieve an independent mechanical steady state position.

50. The space transformer connector of claim 47, wherein at least a portion of the means for providing electrical contact conductive via structures is configured for high frequency.
